(19) United States
(12) Patent Application Publication
(10) Pub. No.: US 2024/0234198 A1
(43) Pub. Date: Jul. 11, 2024

(54) SUBSTRATE HANDLING DEVICE

(71) Applicant: Yield Engineering Systems, Inc., Fremont, CA (US)

(72) Inventors: Greg Pizzo, Gilroy, CA (US); Angelo-Jose Banzon, Milpitas, CA (US); Alan Lee Stone, Bloomingale, CA (US); Jed Hsu, Fremont, CA (US); Joseph Brett, Fremont, CA (US)

(73) Assignee: Yield Engineering Systems, Inc., Fremont, CA (US)

(21) Appl. No.: 18/095,726

(22) Filed: Jan. 11, 2023

(51) Int. Cl. H01L 21/687; H01L 21/3065; H01L 21/67

(52) U.S. Cl. CPC H01L 21/6875; H01L 21/3065; H01L 21/67115; H01L 21/67248; H01L 21/68728

(57) ABSTRACT

A substrate handling device may include a central hub configured to coupled to a rotatable shaft that extends along a central axis of a process chamber. The rotatable shaft may be configured to rotate in the process chamber about the central axis and translate in the process chamber along the central axis. A plurality of radially extending arms may be configured to removably coupled to the central hub. The substrate handling device may include a plurality of substrate supports removably coupled to the plurality of arms and configured to support the substrate. The substrate handling device may also include a plurality of end retainers removably coupled to the plurality of arms.

### TECHNICAL FIELD

The present disclosure relates to a substrate handling device, in particular, to a substrate handling device that may be used in a semiconductor processing apparatus.

### BACKGROUND

A substrate handling device (substrate handler) is used to support one or more substrates in the process chamber of semiconductor processing equipment during processing. Many semiconductor processing equipment need a substrate handling device that is adapted to support different types, shapes, and sizes of substrates within its process chamber. Most conventional substrate handlers are configured to support only one form factor (size, shape, etc.) of a substrate. If a substrate having a different form factor is to be processed in the process chamber, the substrate handler may need to be changed. In some process chambers, the substrate will need to be manipulated (e.g., rotated, translated, etc.) and/or be exposed to different environments (e.g., high/low temperature, harsh chemicals, high/low pressure, etc.) within the process chamber. In some cases, the substrate handler may also need to transport the substrate to different regions within the process chamber. For example, in some cases, the substrate handler may need to transport the substrate from a heating zone to a cooling zone (or vice versa) of the chamber. In some applications, the substrate handler may also need to be electrostatic discharge (ESD) compliant. For many applications, it may also be beneficial to have temperature measurement features in the substrate handler. The substrate handling devices of the current disclosure may satisfy some or all of the above-described needs.

### SUMMARY

Several embodiments of substrate handling devices are disclosed. It is to be understood that both the foregoing general description and the following detailed description are exemplary and explanatory only. As such, the scope of the disclosure is not limited solely to the disclosed embodiments. Instead, it is intended to cover such alternatives, modifications and equivalents within the spirit and scope of the disclosed embodiments. Persons skilled in the art would understand how various changes, substitutions and alterations can be made to the disclosed embodiments without departing from the spirit and scope of the disclosure.

In one aspect, a substrate handling device configured to support a substrate in a process chamber is disclosed. The substrate handling device includes a plurality of arms configured to removably coupled to a central hub. The plurality of arms may be symmetrically positioned about a central axis of the process chamber and may extend radially from the central axis. The central hub may be configured to be coupled to a rotatable shaft extending along the central axis. The rotatable shaft may be configured to rotate in the process chamber about the central axis and translate in the process chamber along the central axis. The central hub may include a hub clamp having a top surface and a bottom surface. The hub clamp may include a central cavity that extends along the central axis from the bottom surface towards the top surface. The central cavity may be configured to receive the rotatable shaft therein. The hub clamp may also include a plurality of recesses on the top surface arranged symmetrically about the central axis and extending radially from the central axis. A first arm of the plurality of arms may be configured to be received in a first recess of the plurality of recesses. The central hub may also include a hub insert including a plurality of spokes arranged symmetrically about the central axis and extending radially from the central axis. A first spoke of the plurality of spokes may be configured to be positioned on top of the first arm received in the first recess of the hub clamp. The central hub may also include a hub cover including a plurality of fingers arranged symmetrically about the central axis and extending radially from the central axis. A first finger of the plurality of fingers may be configured to be positioned on top of the first spoke positioned on top of the first arm received in the first recess of the hub clamp. The substrate handler may also include a plurality of substrate supports. Each substrate support of the plurality of substrate supports may be removably coupled to a different arm of the plurality of arms and a top surface of each substrate support may be configured to support the substrate.

In another aspect, a substrate handling device configured to support a substrate in a process chamber is disclosed. The substrate handling device may include a central hub configured to coupled to a rotatable shaft that extends along a central axis of the process chamber. The rotatable shaft may be configured to rotate in the process chamber about the central axis and translate in the process chamber along the central axis. A plurality of arms may be configured to removably coupled to the central hub. The plurality of arms may be symmetrically positioned about the central axis and extend radially from the central axis. The substrate handling device may include a plurality of substrate supports. Each substrate support of the plurality of substrate supports may be removably coupled to a different arm of the plurality of arms and may include a top surface configured to support the substrate. The substrate handling device may also include a plurality of end retainers. Each end retainer of the plurality of end retainers may be removably coupled to a different arm of the plurality of arms and may include a first surface extending parallel to the central axis and a second surface inclined with the first surface.

### BRIEF DESCRIPTION OF THE DRAWINGS

The accompanying drawings, which are incorporated in and constitute a part of this disclosure, illustrate exemplary embodiments and, together with the description, are used to explain the disclosed principles. In these drawings, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure of the various described embodiments. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing proportional relationships between different features in a figure. Additionally, even if it is not specifically mentioned, aspects described with reference to one embodiment or figure may also be applicable to, and may be used with, other embodiments or figures.

FIGS. 1A-1D are schematic illustrations of exemplary process chambers with a substrate handling device of the current disclosure;

FIG. 2 illustrates an exemplary substrate configured to be supported in the substrate handlers of the current disclosure in the process chamber of FIG. 1D;

FIGS. 3A-3D are illustrations of an exemplary substrate handler of the current disclosure;

FIGS. 4A-4E illustrate different views of some parts of the substrate handler of FIG. 3A;

FIG. 5 is an exemplary temperature detector used with the substrate handlers of the current disclosure; and

FIGS. 6A-6F are illustrations of different views of another exemplary substrate handler of the current disclosure.

### DETAILED DESCRIPTION

All relative terms such as “about,” “substantially,” “approximately,” etc., indicate a possible variation of +10% (unless noted otherwise or another variation is specified). For example, a feature disclosed as being about “t” units long (wide, thick, etc.) may vary in length from (t−0.1t) to (t+0.1t) units. Similarly, a temperature within a range of about 100-150° C. can be any temperature between (100−10%) and (150+10%). In some cases, the specification also provides context to some of the relative terms used. For example, a structure described as being substantially circular or substantially cylindrical may deviate slightly (e.g., 10% variation in diameter at different locations, etc.) from being perfectly circular or cylindrical. Further, a range described as varying from, or between, 1 to 10 (1-10), includes the endpoints (i.e., 1 and 10).

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

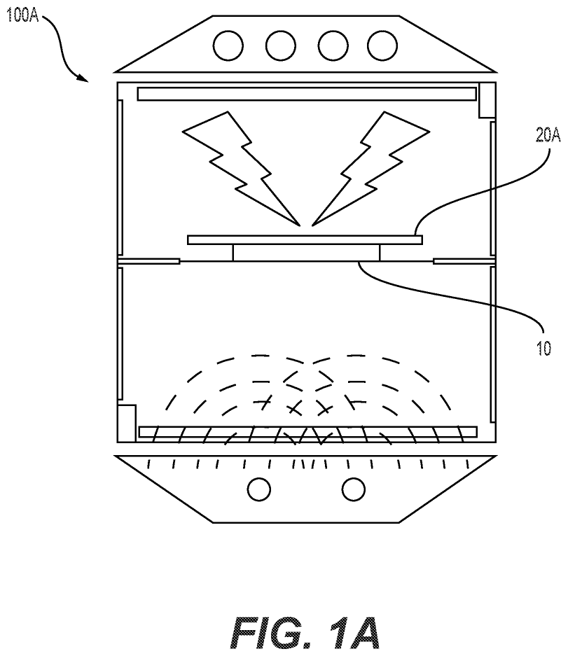

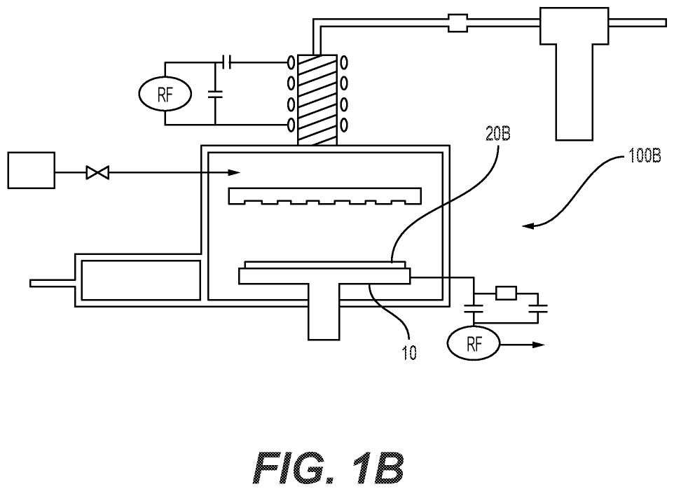

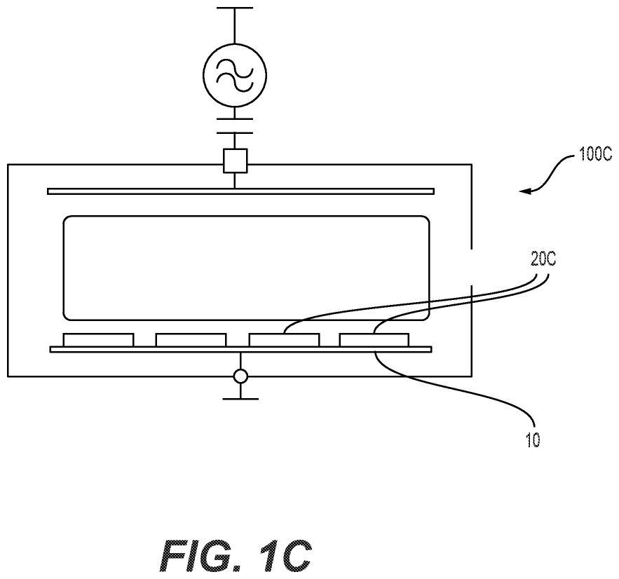

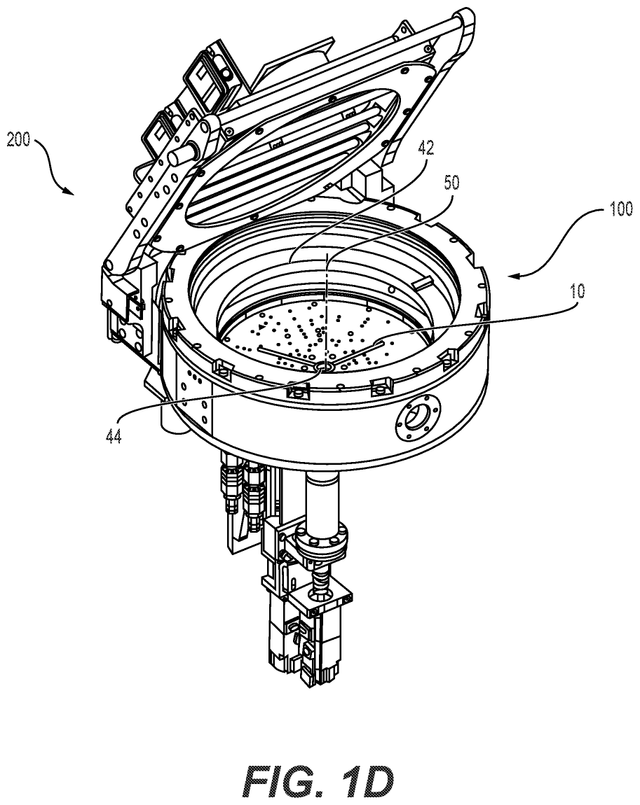

FIGS. 1A-1D are schematic illustrations of some exemplary processing chambers that may use an embodiment of the disclosed substrate handler. FIG. 1A illustrates a process chamber 100A of an annealing device where a substrate 20A (e.g., a silicon wafer, etc.) supported on a substrate handler 10 is exposed to high temperatures for annealing (for example). In the illustrated embodiment, the system uses plasma arc lamps to flash energy (millisecond annealing) onto the topside of substrate 20A to achieve the desired temperature. During processing, substrate handler 10 is also exposed to high temperatures. As another example, FIG. 1B illustrates a process chamber 100B of a thin film coating device (such as, for example, a chemical vapor deposition (CVD) device, plasma vapor deposition (PVD) device, atomic layer deposition (ALD) device, etc.). During CVD, a volatile precursor is injected into process chamber 100B (typically under vacuum) and the chamber is heated to a reaction temperature that causes the precursor gas to react or break down into the desired coating and bond to the surface of a substrate 20B (e.g., wafer, IC devices, etc.) supported on substrate handler 10. Over time the coating material builds on the substrate surface and creates the coating. During PVD, a solid material is vaporized in a vacuum and deposited onto the substrate surface. ALD is a variant of CVD where gaseous reactants or precursors are introduced into process chamber 100B for forming the desired coating material via chemical surface reactions. During the coating process, substrate handler 10 is exposed to different temperatures and chemical compounds. As yet another example, FIG. 1C is an illustration of a process chamber 100C of an etching machine (e.g., wet etching, dry etching, etc.). During etching, material is selectively removed from selected surfaces of substrates 20C (devices, etc.) supported on substrate handler 10 using a liquid, gaseous, or a plasma reagent. During etching, exposed material is removed from the substrate surface by, for example, corrosion. The substrate handler 10 is also subject to the corrosive environment during the etching process. In each of the above-described exemplary process chambers 100A, 100B, 100C, substrate handler 10 is exposed to the adverse environment in the process chamber. Substrate handler 10 is configured to be resistant to these adverse environments. Substrate handler 10 is also configured to support different sizes (200 mm wafer, 300 mm wafer, etc.) and shapes (round wafer, rectangular panel, single IC device, array of IC devices, etc.) of substrates 20A, 20B, 20C thereon for processing.

FIG. 1D illustrates another exemplary process chamber 100 with a substrate handler 10 configured to support a substrate during processing. Process chamber 100 of FIG. 1D is associated with a high temperature processing oven 200 (e.g., a solder reflow oven). U.S. Pat. No. 11,296,049, assigned to the assignee of the current application, describes the features of an exemplary processing oven 200. This reference is incorporated by reference in its entirety herein. For ease of description, features of the substrate handlers of the current disclosure will be described with reference to process chamber 100 (of FIG. 1D). However, it should be noted that this is not a limitation and substrate handlers of the current disclosure may be used with any type of process chamber (e.g., process chamber 100A-100C) of any apparatus. Substrate handler 10 is configured to support any type of substrate (e.g., circular wafer (200 mm, 300 mm, etc.), square/rectangular panel, organic/ceramic substrate, one or more IC devices or semiconductor packages, printed circuit boards (PCB), etc.) and adapted to subject the substrate to a high temperature solder reflow process. In the discussion below, a semiconductor wafer will be described as the substrate (not shown in FIG. 1D) supported on substrate handler 10. However, this is only exemplary and the substrate handlers of the current disclosure may support substrates of any size and shape (e.g., a round wafer, a rectangular panel, a single IC device, multiple IC devices, multiple wafers, printed circuit boards, etc.).

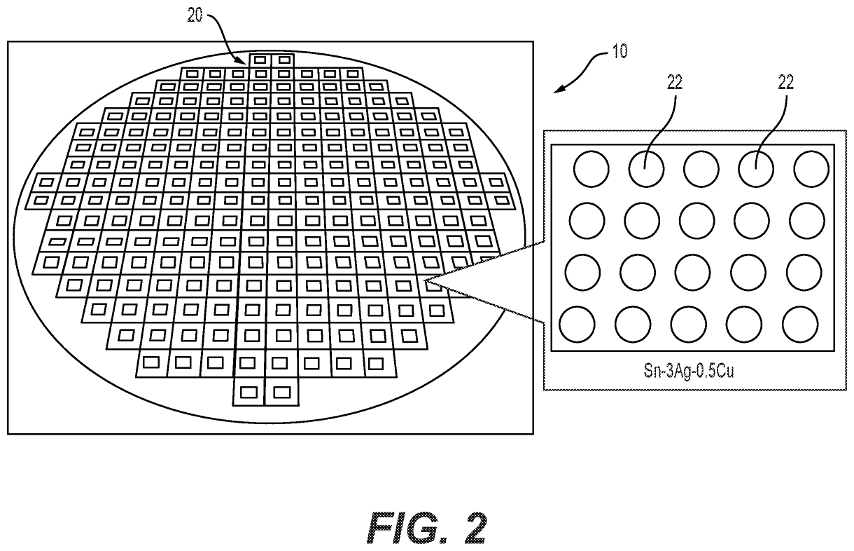

FIG. 2 illustrates an exemplary substrate 20 that may be supported on substrate handler 10 in process chamber 100. Substrate 20 of FIG. 2 includes multiple IC dies (or IC chips) with a solder material (lead-tin, gold-tin, etc.) deposited on the I/O pads of the individual dies. As would be recognized by a person skilled in the art, after processing of the IC dies is compete, substrate 20 may be diced or cut to form individual IC dies. In some embodiments, substrate 20 may be subject to a reflow process (e.g., to form solder bumps 22) while it is supported on substrate handler 10. To subject substrate 20 to a reflow process (or any other process) in process chamber 100 of oven 200 (see FIG. 1D), a robotic manipulator or arm (not shown) associated with oven 200 may insert the substrate into process chamber 100 through an inlet port 42 and deposit substrate on substrate handler 10. Processing may then be carried out in oven 200. U.S. Pat. Nos. 7,727,588, 8,252,375, 8,361,548, 10,147,617, 10,319,612, 10,490,431, 10,840,068, 11,456,274 and 11,465,225, assigned to the assignee of the current application, describe exemplary processes that may be applied to the substrate supported on the disclosed substrate handler. These references are also incorporated by reference in their entireties herein.

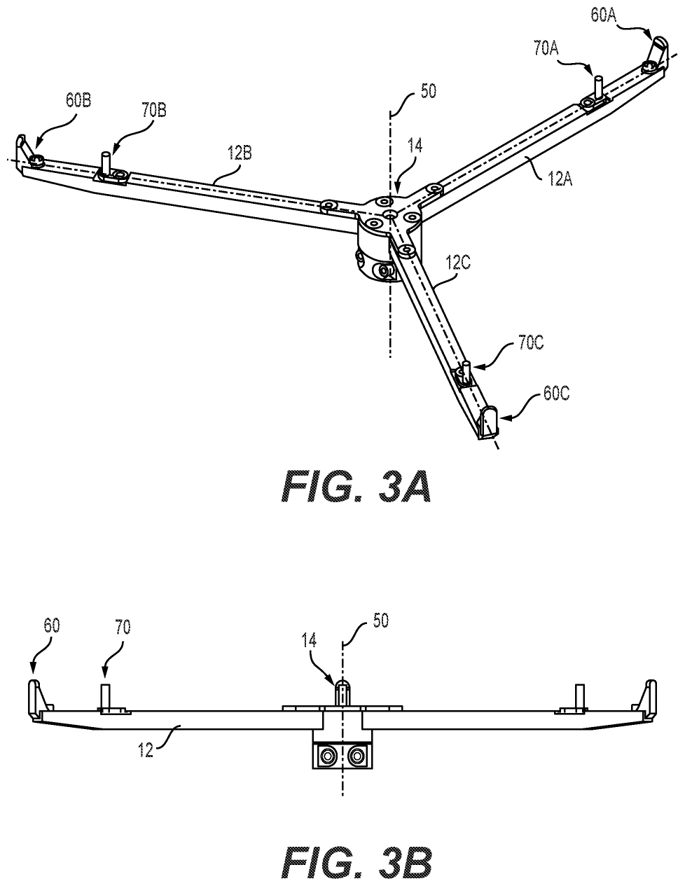

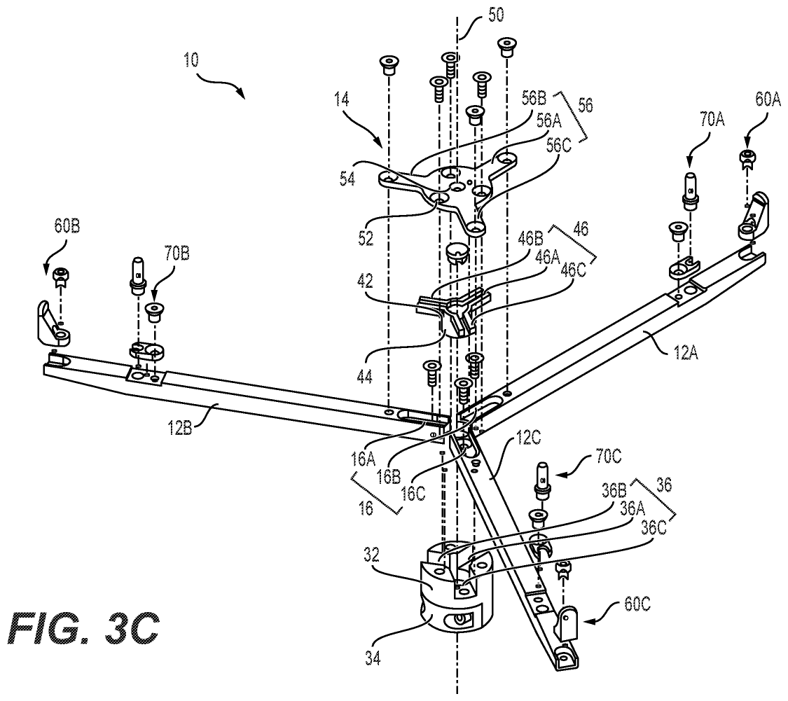

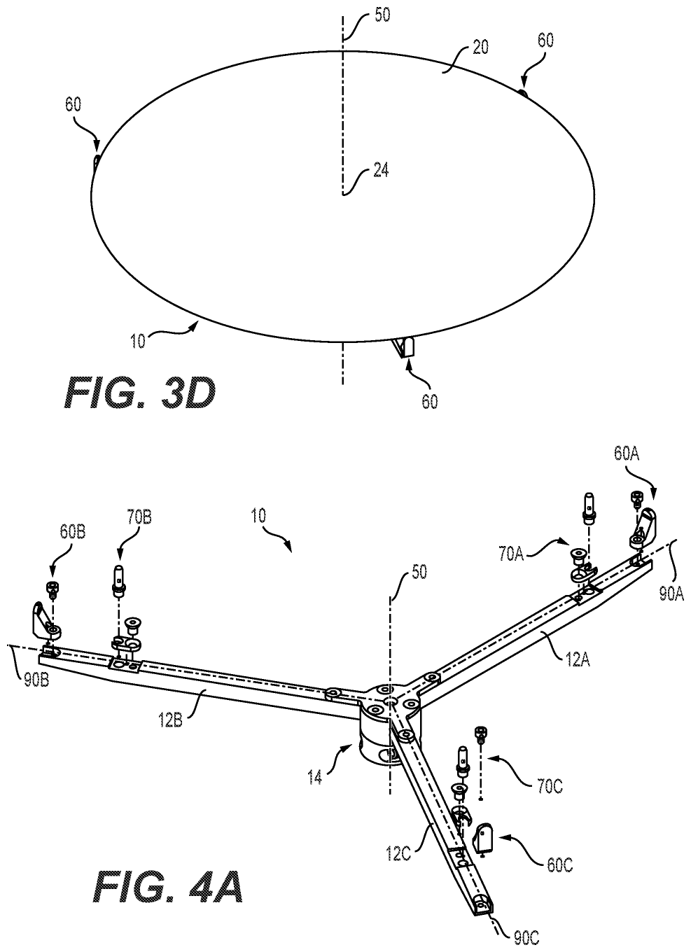

FIGS. 3A-3D are illustrations of an exemplary substrate handler 10 separated from process chamber 100. FIG. 3A illustrates a perspective view and FIG. 3B illustrates a side view of substrate handler 10. FIG. 3C illustrates an exploded view showing the different components of substrate handler 10 and FIG. 3D is a view showing a substrate 20 supported on substrate handler 10. In the discussion below, reference will be made to FIGS. 3A-3D. Substrate handler 10 may include a central hub 14 configured to be coupled to a rotatable shaft 44 of oven 200 (FIG. 1D) such that substrate handler 10 rotates with shaft 44 about a central axis 50 (e.g., a vertical axis) of processing chamber 100. Hub 14 may be coupled to shaft 44 in any suitable manner. When a substrate 20 is supported on substrate handler 10 as shown in FIG. 3D, the substrate 20 also rotates with substrate handler 10 when shaft 44 rotates. Substrate handler 10 may include a plurality of arms 12A, 12B, 12C that extend radially outward from hub 14 (for example, like spokes extending from the central hub of a wheel). Although FIGS. 3A-3D illustrate an embodiment of substrate handler 10 with three arms, this is only exemplary. In general, substrate handler 10 may include any number (4, 5, 6 etc.) of arms. For example, a substrate handler 10 configured to support a rectangular (or a square) substrate may include four arms, and a substrate handler 10 configured to support an irregular shaped substrate (e.g., a polygon shaped) may include a different number of arms.

Arms 12A, 12B, and 12C may be removably attached to hub 14 such that they may be separated and reattached to hub 14. For the sake of brevity, arms 12A, 12B, and 12C will be collectively and individually referred to as arm(s) 12. For example, in some embodiments, when a substrate handler 10 configured to support a 200 mm (diameter) wafer is refitted to support a 300 mm wafer, the arms 12 of the substrate handler may be removed from hub 14 and different arms 12 attached. Arms 12 may be removably attached to hub 14 by any suitable mechanism. For example, in some embodiments, as best seen in FIG. 3C, screws and/or other mechanical fasteners may be used to attach the arms 12 to hub 14. As shown in FIG. 1C, hub 14 may include multiple components that cooperate to removably attach the arms 12 to rotatable shaft 44 of oven 200. In the illustrated embodiment of substrate handler 10 (e.g., in FIG. 3C), these multiple components of hub 14 include a hub clamp 32, a hub insert 42, and a hub cover 52.

Hub clamp 32 may be a generally cylindrical component with a central cavity 34 on its bottom surface (not seen in FIG. 1C). The central cavity 34 may be configured to receive and retain rotatable shaft 44 of oven 200. In some embodiments, cavity 34 may be a blind recess that extends through hub clamp 32 along the central axis 50 of oven 200. The cross-sectional shape (e.g., in a plane perpendicular to central axis 50) and size of cavity 34 may correspond to (e.g., substantially similar to) those of shaft 44 such that shaft 44 may be received in cavity 34. In general, cavity 34 and shaft 44 may have any cross-sectional shape (e.g., circular, square, rectangular, polygonal, star shape, etc.). To enable the shaft 44 to be received in cavity 34, the cross-sectional size (e.g., width, diameter, etc.) of cavity 34 may be slightly larger than that of shaft 44. In some embodiments, a set screw (or another mechanical fastener) may be used to lock the shaft 44 in cavity 34 such that hub clamp 32 rotates along with shaft 44 with no (or minimal) slippage (or relative motion) between them. The top surface of hub clamp 32 includes multiple radially extending recesses 36 configured to receive arms 12 of substrate handler 10 therein. In some embodiments, as illustrated in FIG. 3C, the multiple recesses 36 may intersect at the central axis 50. In general, the number of recesses 36 may be equal to the number of arms 12. For example, when substrate handler 10 has three arms (12A, 12B, 12C), three recesses (36A, 36B, 36C) may extend radially from central axis 50 along the top surface of hub clamp 32. Each arm 12 may be received in a separate recess 36. For example, arm 12A may be received in recess 36A, arm 12B may be received in recess 36B, and arm 12C may be received in recess 36C. In some embodiments, recesses 36A, 36B, 36C (and arms 12A, 12B, 12C) may extend transverse to, and be arranged symmetrically about, the central axis 50. The cross-sectional (e.g., in a plane parallel to central axis 50) shape of each recess 36 may correspond to the cross-sectional shape of the arm 12 that is received in the recess. Although not a requirement, in some embodiments, both arms 12 and recesses 36 may have rectangular or a square cross-sectional shape.

With the arms 12 received in the recesses 36 of hub clamp 32, hub insert 42 is positioned atop the top surface of the hub clamp 32 and the arms 12. The top surface of each arm 12 includes a recess 16 that extends along a length of the arm 12. Recess 16 may be centrally located on the arm and have a width smaller than the width of the arm 12. Hub insert 42 may include a central plug 44 with multiple fingers 46 projecting radially outward from central plug 44. The number of radially extending fingers 46 may be equal to the number of arms 12. For example, when substrate handler 10 has three arms (12A, 12B, 12C), hub insert 42 may include three fingers (46A, 46B, 46C) that extend radially from central plug 44. In some embodiments, the multiple fingers 46 may be symmetrically arranged about central plug 44. When arms 12 are disposed in the recesses 36 of hub clamp 32, and hub insert 42 is positioned atop these assembled components, fingers 46 are received in the recesses 16 on the top surface of arms 12. While in this configuration, central plug 44 (of hub insert 42) extends along the central axis 50 between the arms 12. For example, finger 46A is received in recess 16A of arm 12A, finger 46B is received in recess 16B of arm 12B, and finger 46C is received in recess 16C of arm 12C. In some embodiments, the radial length and width of each finger 46 may correspond to (e.g., similar to) the length and width of the recess 16 that receives the finger 46. Since each finger 46 is received in a recess, the length and width of the finger may be smaller (e.g., slightly smaller) than that of the recess.

Hub cover 52 may then be positioned atop the assembled hub clamp 32, arms 12, and hub insert 42 and the assembly fastened together using mechanical fasteners (e.g., screws). Hub cover 52 may include a central region 54 with multiple fingers 56 that project radially outward from central region 54. The number of radially extending fingers 56 may be equal to the number of arms 12. For example, when substrate handler 10 has three arms (12A, 12B, 12C), hub cover 52 may include three fingers (56A, 56B, 56C) that extend radially outward from its central region 54. The multiple fingers 56 may be symmetrically arranged about central region 54. When the components of hub 14 are assembled together, fingers 56 of hub cover 52 will be positioned on top of and cover the fingers 46 of hub insert 42 disposed in the recesses 16 of the arms 12. For example, finger 56A extends radially along the top surface of arm 12A to cover finger 46A disposed in recess 16A of arm 12A, etc. In some embodiments, the width of each finger 56 may correspond to (e.g., be similar to) the width of the arm 12 that it is positioned on top of. In some embodiments, it may be wider.

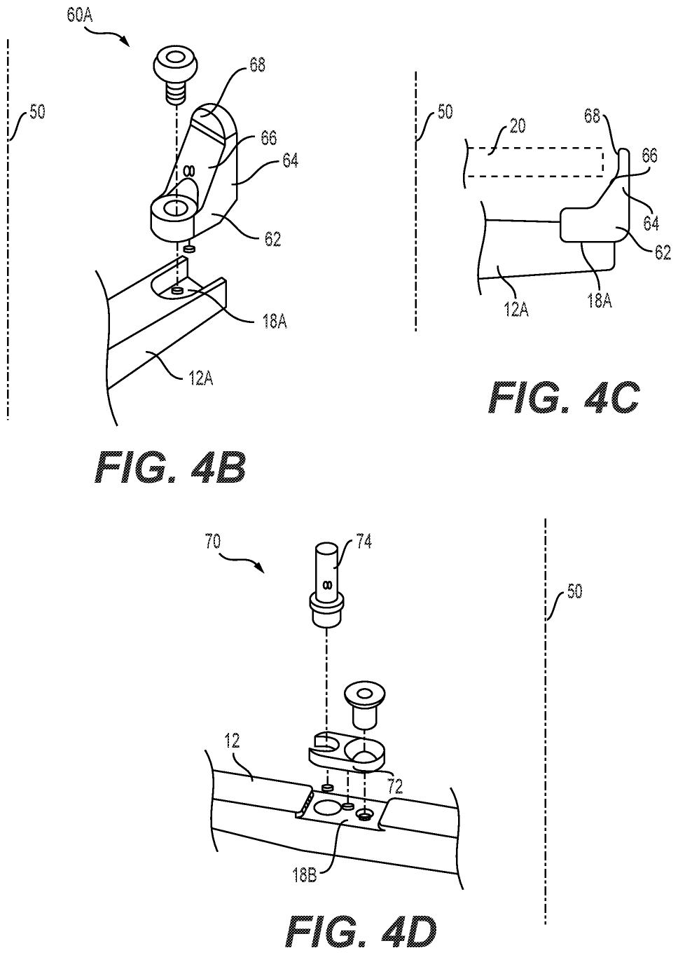

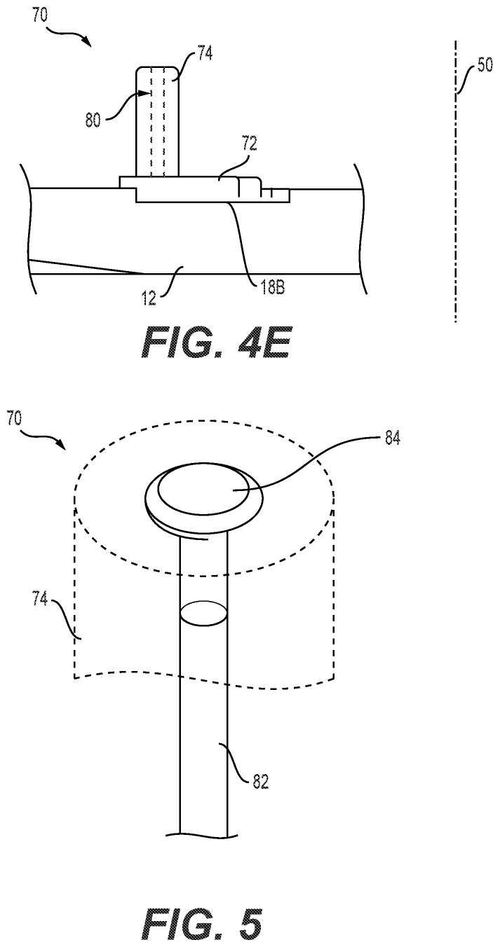

Each arm 12 of substrate handler 10 may include removably attached support fixtures configured to support and retain a substrate on substrate handler 10 as the substrate handler rotates and translates along one or more axes. In some embodiments, these support fixtures may include end retainers 60A, 60B, 60C and substrate supports 70A, 70B, 70C. End retainers 60A, 60B, 60C and substrate supports 70A, 70B, 70C will be collectively and individually referred to as end retainer(s) 60 and substrate support(s) 70, respectively. In some embodiments, both end retainers 60 and substrate supports 70 may be made of electrostatic discharge (ESD) compliant materials. In general, any ESD compliant material known in the art (e.g., commercially available ESD compliant materials) may be used. In some embodiments, a material such as, for example, Silicon Carbide (SiC), Polybenzimidazole (PBI), Polyimide with carbon, etc. may be used. FIG. 4A illustrates an exemplary support holder 10 with end retainers 60 (60A, 60B, 60C) and substrate supports 70 (70A, 70B, 70C). In some embodiments, substrate supports 70 and end retainers 60 may be configured to support specific configurations (e.g., size, shape, etc.) of substrates. For example, the substrate supports 70 and/or end retainers 60 may be replaced when the form factor of the substrate to be supported on substrate handler 10 changes. In some embodiments of substrate handler 10, only one of substrate support 70 or end retainer 60 may be provided.

End retainer 60 may assist a substrate supported by substrate handler 10 (e.g., substrate 20 of FIG. 3D) to be retained on substrate handler 10 during rotation. End retainers 60 may also assist in keeping the center axis 24 of substrate 20 coaxial with the central axis 50 of oven 200 during rotation. End retainers 60 may be removably coupled to arms 12 using any suitable attachment mechanism (e.g., screws, etc.). Although not a requirement, in some embodiments, end retainers 60 attached to each arm 12 may be similar in size and shape. For example, as illustrated in FIGS. 3A and 4A, end retainers 60A, 60B, and 60C may be similar in size and shape. However, this is not a requirement. In some embodiments, end retainers 60 may be removably coupled to radially outermost end of each arm 12. However, this is also not a requirement. In some embodiments, the location of arm 12 where end retainer 60 is attached may depend on the size of substrate 20 supported by substrate handler 10. For example, when a 300 mm wafer is supported by substrate handler 10, end retainers 60 may be connected to the outermost end of arms 12 (see, for example, FIGS. 3A, 3D). If a 200 mm substrate is supported by substrate handler 10, end retainers 60 may be repositioned to be inwards of the outermost end of arm 12 (for example, 50 mm inwards from the radially outermost end of each arm 12). Although not shown in FIG. 3C, in some embodiments, arm 12 may include features (e.g., holes, etc.) to attach end retainer 60 at different locations along its length.

FIG. 4B is an enlarged perspective view of an end retainer 60 configured to be removably attached to arm 12 of substrate handler 10, and FIG. 4C is a schematic side view of an end retainer 60 attached to arm 12. With reference to FIGS. 4B and 4C, end retainer 60 includes a base 62 that extends in the direction of arm 12 and a ridge 64 that extends upwards from base 62. Base 62 may be attached to arm 12 using, for example, screws. Arm 12 may include a pocket or a recess 18A configured to receive at least a portion of base 62 when base 62 is attached to arm 12. Ridge 64 of end retainer 60 includes multiple surfaces angled with respect to each other and facing the central axis 50. These angled surfaces include a first surface 68 and a second surface 66 that makes an obtuse angle with the first surface 68. First surface 68 may be disposed at the top end of ridge 64 and second surface 66 may be disposed below first surface 68 (e.g., between first surface 68 and base 62). In some embodiments, first surface 68 may extend substantially transverse to the top surface of arm 12 and/or substantially parallel to central axis 50. In some embodiments, the inclined second surface 66 may make an obtuse angle with the top surface of the arm 12 and/or an acute angle with central axis 50. First and second surfaces 68, 66 may be ESD compliant surfaces (e.g., made of an ESD compliant material). When substrate 20 is supported on substrate handler 10, the inclined second surface 66 allows the substrate to slide thereon and may assist in keeping substrate center axis 24 coaxial with the oven central axis 50, while first surface 68 may block the substrate from sliding past the edge of arm 12 during rotation (see FIG. 3D). It should be noted that the shape of the end retainer illustrated and described herein is not a requirement. In general, the shape and structure of the end retainer may depend on the application (for example, the shape of the substrate supported on substrate handler 10).

FIG. 4D is an enlarged perspective view of a substrate support 70 that is configured to be removably attached to arm 12 of substrate handler 10, and FIG. 4E is a schematic side view of a substrate support 70 attached to arm 12. With reference to FIGS. 4D and 4E, substrate support 70 includes a base 72 attached (e.g., using mechanical fasteners, etc.) to arm 12 and a post 74 or column attached (e.g., snap fitted, using mechanical fasteners, etc.) to base 72. When substrate 20 is supported by substrate handler 10, the back surface of substrate 20 may rest on the top surface of post 74. In general, base 72 extends in the direction of arm 12 and post 74 extends in a direction transverse to arm 12. In some embodiments, post 74 may extend parallel to central axis 50. Arm 12 may include a pocket or a recess 18B configured to receive at least a portion of base 72 when base 72 is attached to arm 12. In some embodiments, base 74 and/or post 74 of substrate support 70 may be made of an ESD compliant material.

In some embodiments, a temperature detector 80 may extend through post 74 of substrate support 70 and physically contact substrate 20 supported on support holder 10 to measure the temperature of the substrate. However, physically contacting the substrate is not a requirement, and in some embodiments (e.g., where post 74 is made of a temperature conducting material) temperature detector 80 may be embedded in post 74 and it may detect the temperature of substrate 20 through post 74. Any type of temperature detecting device (thermocouple, resistance temperature detector (RTD), pyrometer, etc.) may be used as temperature detector 80. FIG. 5 is an illustration of an exemplary temperature detector 80 coupled to post 74 of substrate support 70. As illustrated in FIG. 5, temperature detector 80 may include a temperature sensor 82 in the form of a cable or a wire connected to a cap 84 at its distal end. When installed in post 74, the distal most end of the cap 84 may protrude from the end face of post 74 to contact substrate 20. In some embodiments, as illustrated in FIG. 5, cap 84 may be mushroom shaped with an enlarged surface area at one end (distal end) and a hollow cylindrical section at the opposite end. The enlarged surface area of cap 84 that contacts the substrate may provide a highly conductive thermal sensing area that improves accuracy and sensitivity of temperature measurement. In some embodiments, temperature sensor 82 may be connected to cap 84 by inserting the elongate temperature sensor 82 into the hollow cylindrical section of cap 84 and crimping the cylindrical section to firmly connect both parts. In some embodiments, all substrate supports 70 (e.g., 70A, 70B, 70C of FIG. 3A) of substrate handler 10 will have a temperature detector 80 incorporated therein. In some embodiments, only selected (e.g., one substrate support 70) will include a temperature detector 80.

Temperature detector 80 may be connected to a control system of oven 200. The control system may control the operation of oven 200 based at least partly on the temperature of substrate 20 measured by temperature detector 80. For example, in some embodiments, the control system may control the temperature (or temperature ramp rate, cooling rate, etc.) of oven 200 based on the measured temperature from temperature detector 80 (e.g., using a feedback loop). For example, as disclosed in U.S. Pat. No. 11,296,049 (which is incorporated by reference in its entirety herein), oven 200 may be heated using multiple lamps. In some embodiments, the power directed to the lamps and/or the number of lamps activated at any time may be controlled by the control system based on the temperature measured by temperature detector 80. As also disclosed in U.S. Pat. No. 11,296,049, substrate handler 10 may vertically move to transport substrate 20 to different temperature zones of oven 200. In some embodiments, the control system may control the movement of substrate handler 10 based on the measured temperature by temperature detector 80.

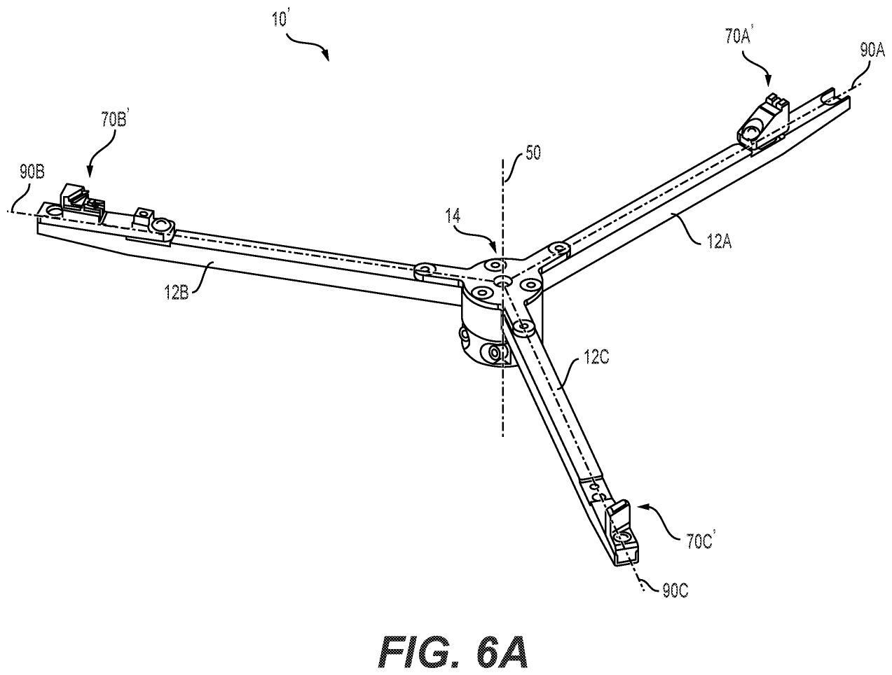

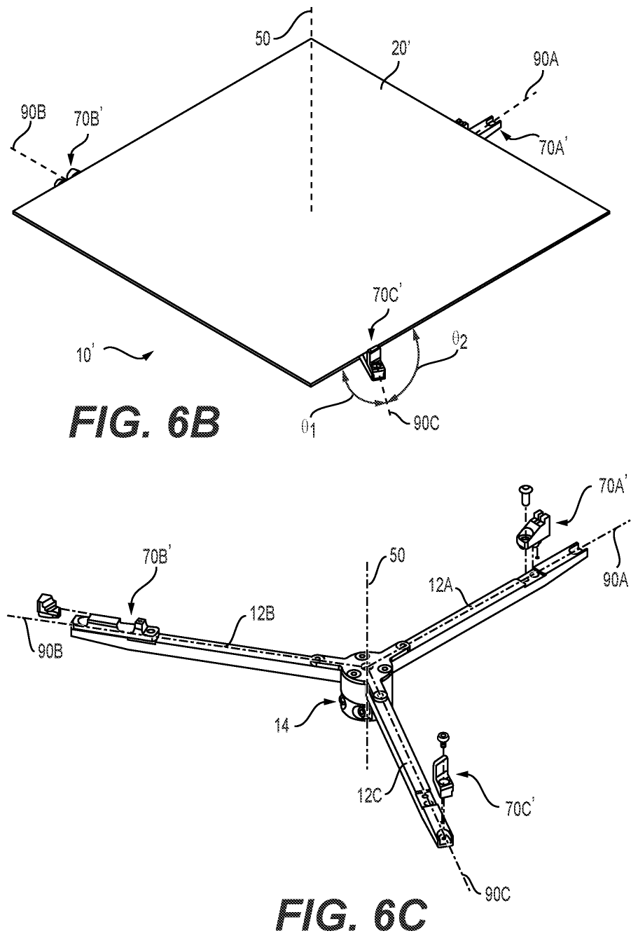

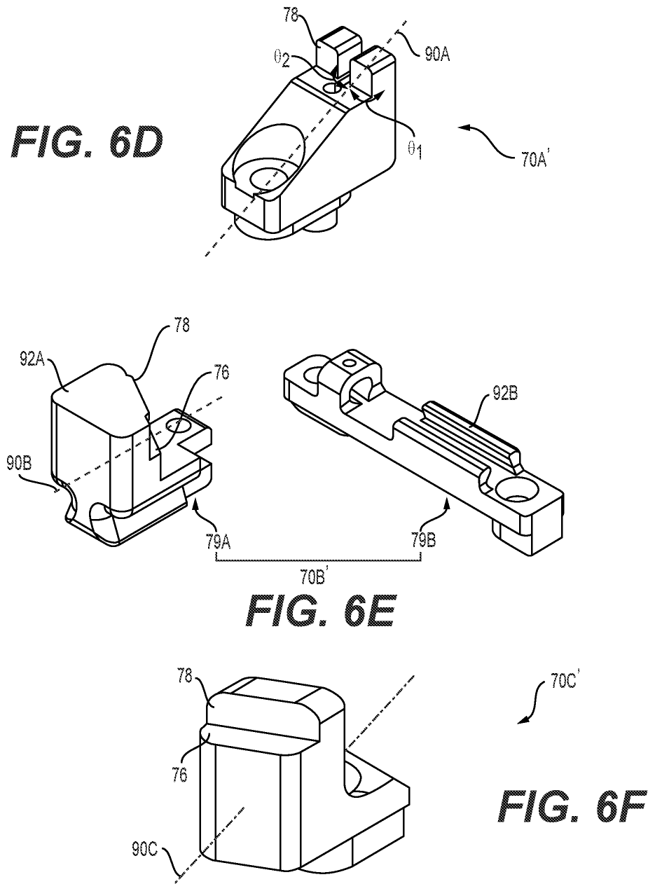

The shape of substrate support 70 illustrated (in FIGS. 3A-3C and 4A, 4D, and 4E) and described above is only exemplary. In general, the shape and size of the substrate support 70 (and end retainer 60) may depend on the application (for example, the shape and size of the substrate supported on substrate handler 10). FIG. 6A illustrates another exemplary substrate handler 10′ with a different configuration of substrate supports 70A′, 70B′, and 70C′. As illustrated in FIG. 6B, substrate handler 10′ is adapted to support a substrate 20′ with linear sides (e.g., square, rectangular, etc.). Although substrate handler 10′ is illustrated as having three arms 12, this is only exemplary. As explained previously, in some embodiments substrate handler 10′ may have a different number or arms 12 (e.g., four arms, five arms, etc.). Further, although only substrate supports 70′ are shown in FIG. 6A (i.e., no end retainers), in some embodiments end retainers may also be provided. Substrate supports 70′ (and end retainers, if any) of substrate handler 10′ are removably attached to arms 12 (see FIG. 6C). Although not illustrated in FIG. 6C, some or all of the substrate supports 70′ may also include temperature detectors 80 (e.g., similar to those described with reference to FIG. 5). The substrate supports 70′ of substrate handler 10′ are shaped to support the form factor of substrate 20′ supported by substrate handler 10′. When a substrate of a different form factor is to be supported, the substrate supports may be removed and replaced with more suitable substrate supports.

FIGS. 6D-6F are enlarged views of substrate supports 70A′, 70B′, and 70C′ of substrate handler 10′ illustrated in FIG. 6C. With reference to these figures, each of substrate supports 70A′, 70B′, 70C′ include a horizontal first surface 76 and a vertical second surface 78. When substrate 20′ is supported on substrate handler 10′, the substrate may rest on first surfaces 76 of substrate supports 70′. And when substrate 20′ rotates, the second surfaces 78 may prevent the substrate from sliding past the first surface. In some embodiments, first and second surfaces 76, 78 may be transverse or perpendicular to each other. It should be noted that, in the embodiment of substrate handler 10′ illustrated in FIG. 6B (e.g., substrate handler 10′ with three arms 12 is used to support a rectangular substrate 20′), the edges of substrate 20′ that rest on (and intersect) some arms 12 do not extend transverse to the longitudinal axis 90 of the arm 12. Instead, some edges of substrate 20′ are inclined or non-perpendicular (i.e., makes an acute angle θ₁ or obtuse angle θ₂) with respect to the longitudinal axis 90 of the arm 12 that they are resting on. For example, the edge of substrate 20′ resting on arm 12B is inclined with respect to longitudinal axis 90B of arm 12B, the edge of substrate 20′ resting on arm 12C is inclined with respect to longitudinal axis 90C of arm 12C, etc. To enable substantially the entire width of second surface 78 of each substrate support 70′ to engage with the corresponding edge of substrate 20′, second surface 78 (of each substrate support 70′) may be similarly inclined with respect to the longitudinal axis 90 of the arm 12 (that the substrate support is attached to). For example, second surface 78 of substrate support 70B′ is inclined with respect to longitudinal axis 90B of arm 12B to fully engage with the edge of substrate 20′ that is supported by arm 12B. It should be noted that the amount of inclination may depend on the application (for e.g., on the number of arms 12 and the number of linear sides of substrate 20′). For example, in embodiments where a 4-sided (e.g., square, rectangular, etc.) substrate 20′ is supported by a substrate handler 10′ having four arms 12, the edge of substrate 20′ resting on each arm may be perpendicular to the longitudinal axis 90 of the arm. In this case, second surface 78 of each substrate support 70′ may also similarly extend perpendicular to the longitudinal axis 90 of the corresponding arm 12.

To load a substrate 20′ on support holder 10′ (or substrate 20 on support holder 10), a robotic arm of oven 200 may insert the substrate into process chamber 100 through inlet port 42 (see FIG. 1D) and deposit the substrate on the substrate handler 10. The substrate supports 70 may then support the substrate in substrate handler. In some embodiments, as illustrated in FIG. 6E, some or all of substrate supports 70′ may have multiple parts movably (or slidably) coupled together (see substrate support 70B′ of FIG. 6A) to enable the substrate to be securely held between the substrate supports. For example, substrate support 70B′ includes a first part 92A coupled via a spring (not shown) to a second part 92B (see FIG. 6E). When attached to the arm, first part 92A may be spring loaded against the second part 92B such that the first part 92A can be moved away (e.g., in the direction of the longitudinal axis 90B of the arm) from second part 92B to load the substrate on substrate handler 10′ between its substrate supports 70′.

It should be noted that the shape and structure of the arms, substrate supports, and end retainers of the substrate handlers described above are only exemplary. As a person skilled in the art would recognize, many variations are possible. Furthermore, although in the description above, some features were disclosed with reference to specific embodiments, a person skilled in the art would recognize that this is only exemplary, and the features are applicable to all disclosed embodiments. Other embodiments of the apparatus, its features and components, and related methods will be apparent to those skilled in the art from consideration of the disclosure herein.

What is claimed is:

1. A substrate handling device configured to support a substrate in a process chamber, comprising:
a plurality of arms configured to removably coupled to a central hub, the plurality of arms symmetrically positioned about a central axis of the process chamber and extending radially from the central axis;
the central hub configured to coupled to a rotatable shaft extending along the central axis, the rotatable shaft being configured to rotate in the process chamber about the central axis and translate in the process chamber along the central axis, wherein the central hub includes,
(a) a hub clamp having a top surface and a bottom surface, the hub clamp including (i) a central cavity extending along the central axis from the bottom surface towards the top surface, the central cavity being configured to receive the rotatable shaft therein, and (ii) a plurality of recesses on the top surface arranged symmetrically about the central axis and extending radially from the central axis, wherein a first arm of the plurality of arms is configured to be received in a first recess of the plurality of recesses,
(b) a hub insert including a plurality of spokes arranged symmetrically about the central axis and extending radially from the central axis, wherein a first spoke of the plurality of spokes is configured to be positioned on top of the first arm received in the first recess of the hub clamp, and
(c) a hub cover including a plurality of fingers arranged symmetrically about the central axis and extending radially from the central axis, wherein a first finger of the plurality of fingers is configured to be positioned on top of the first spoke positioned on top of the first arm received in the first recess of the hub clamp; and
a plurality of substrate supports, wherein each substrate support of the plurality of substrate supports is removably coupled to a different arm of the plurality of arms, wherein a top surface of each substrate support is configured to support the substrate.

2. The substrate handling device of claim 1, wherein a first substrate support of the plurality of substrate supports includes a temperature detector configured to measure a temperature of the substrate supported on the top surface of the first substrate support.

3. The substrate handling device of claim 2, wherein the first substrate support includes a post extending transverse to an arm of the plurality of arms that the substrate support is coupled to, and wherein the temperature detector is configured to extend through the post to contact the substrate.

4. The substrate handling device of claim 1, further including a plurality of end retainers, wherein each end retainer of the plurality of end retainers is removably coupled to a different arm of the plurality of arms.

5. The substrate handling device of claim 4, wherein each end retainer of the plurality of end retainers includes a first surface extending parallel to the central axis and a second surface inclined with the first surface.

6. The substrate handling device of claim 5, wherein the second surface is disposed between the first surface and the arm that the end retainer is coupled to.

7. The substrate handling device of claim 1, wherein a top surface of the first arm includes a radially extending recess, wherein the first spoke is configured to be positioned in the radially extending recess of the first arm.

8. The substrate handling device of claim 1, wherein the plurality of arms include three arms.

9. The substrate handling device of claim 1, wherein the plurality of arms include four arms.

10. The substrate handling device of claim 1, wherein the hub insert further includes a central plug, the plurality of spokes extending radially from the central plug, and wherein the central plug is configured to be received in a space between the plurality of arms.

11. A substrate handling device configured to support a substrate in a process chamber, comprising:
a central hub configured to coupled to a rotatable shaft extending along a central axis of the process chamber, the rotatable shaft being configured to rotate in the process chamber about the central axis and translate in the process chamber along the central axis;
a plurality of arms configured to removably coupled to the central hub, the plurality of arms symmetrically positioned about the central axis and extending radially from the central axis;
a plurality of substrate supports, wherein each substrate support of the plurality of substrate supports is removably coupled to a different arm of the plurality of arms and includes a top surface configured to support the substrate; and
a plurality of end retainers, wherein each end retainer of the plurality of end retainers is removably coupled to a different arm of the plurality of arms and includes a first surface extending parallel to the central axis and a second surface inclined with the first surface.

12. The substrate handling device of claim 11, wherein a first substrate support of the plurality of substrate supports includes a temperature detector configured to measure a temperature of the substrate supported by the plurality of substrate supports.

13. The substrate handling device of claim 12, wherein the first substrate support includes a post extending transverse to an arm of the plurality of arms that the first substrate support is coupled to, and wherein the temperature detector is configured to extend through the post to contact the substrate.

14. The substrate handling device of claim 11, wherein the central hub includes (a) a hub clamp having a top surface and a bottom surface, the hub clamp including (i) a central cavity extending along the central axis from the bottom surface towards the top surface, the central cavity being configured to receive the rotatable shaft therein, and (ii) a plurality of recesses on the top surface arranged symmetrically about the central axis and extending radially from the central axis, wherein a first arm of the plurality of arms is configured to be received in a first recess of the plurality of recesses.

15. The substrate handling device of claim 14, wherein the central hub further includes (b) a hub insert including a plurality of spokes arranged symmetrically about the central axis and extending radially from the central axis, wherein a first spoke of the plurality of spokes is configured to be positioned on top of the first arm received in the first recess of the hub clamp.

16. The substrate handling device of claim 15, wherein the hub insert further includes a central plug, the plurality of spokes extending radially from the central plug, and wherein the central plug is configured to be received in a space between the plurality of arms.

17. The substrate handling device of claim 15, wherein the central hub further includes (c) a hub cover including a plurality of fingers arranged symmetrically about the central axis and extending radially from the central axis, wherein a first finger of the plurality of fingers is configured to be positioned on top of the first spoke positioned on top of the first arm received in the first recess of the hub clamp.

18. The substrate handling device of claim 11, wherein the plurality of arms include three arms.

19. The substrate handling device of claim 11, wherein the plurality of arms include four arms.

20. The substrate handling device of claim 11, wherein the plurality of substrate supports and the plurality of end retainers are made of an ESD compliant material.
